(19) United States
(12) Patent Application Publication
(10) Pub. No.: US 2009/0108053 A1
(43) Pub. Date: Apr. 30, 2009

(54) Solder Ball Placement Vacuum Tool

(76) Inventor: Wyatt A. Huddleston, Allen, TX (US)

Correspondence Address: TEXAS INSTRUMENTS INCORPORATED, P O BOX 655474, M/S 3999, DALLAS, TX, 75265, US

(21) Appl. No.: 11/924,974

(22) Filed: Oct. 26, 2007

(51) Int. Cl. B23K 37/00

(52) U.S. Cl. 228/246; 228/176; 228/41

(57) ABSTRACT

The invention provides apparatus, systems, and methods for positioning solder balls in a desired arrangement on a surface. In preferred embodiments of the invention, a vacuum head body is configured to direct a vacuum force through a vacuum chamber wherein a permeable vacuum plate encloses the vacuum chamber. A stencil adjacent to the vacuum plate includes solder ball niches configured to capture solder balls. The vacuum head may be used to pick up solder balls within the solder ball niches by way of vacuum force, and may be caused to release the solder balls from the solder ball niches by relaxing the vacuum force. According to particular preferred embodiments, the permeable vacuum plate is a porous metallic plate, such as a plate of sintered metal. Preferred embodiments also disclose interchangeable stencils for use with the permeable vacuum plate.

### TECHNICAL FIELD

The invention relates to electronic semiconductor devices and manufacturing. More particularly, the invention relates to apparatus, systems, and methods useful in semiconductor device manufacturing processes for placement of an array of solder balls onto a surface.

### BACKGROUND OF THE INVENTION

The use of various forms of BGA (ball grid array) packages for semiconductor integrated circuits has become fairly common in the arts. A standard approach to manufacturing BGA packages is to firmly attach solder balls to solder pads (or electrodes) arranged on a receiving surface, such as a BGA substrate. Such a manufacturing process typically includes solder ball placement, semiconductor device placement, and subsequent reflow. Solder ball placement involves aligning the solder balls with the positions of the solder pads and placing the solder balls onto these positions. The device is typically placed on the solder balls. Reflow is a process in which solder balls melt, reflow, and harden onto the solder pads of the substrate to create the electrical couplings between the semiconductor device and the substrate.

Current methods and systems for solder ball placement usually involve sweeping or rolling solder balls onto a template approximately corresponding to the arrangement of the receiving surface, usually an array arranged in a grid. A pick-up head is generally used to pick up the solder balls from the template, move them into position over the receiving surface, and release them onto their respective positions, e.g., on contact pads, on the receiving surface for subsequent reflow.

Pick-up heads used for solder ball placement typically use a vacuum force to hold the solder balls against a bearing surface. When the pick-up head is properly positioned, the vacuum force may be interrupted in order to release the solder balls. Although relatively successful in terms of solder ball handling, problems remain with the vacuum pick-up heads currently used in the arts. The vacuum pick-up heads used for handling solder balls include a precision-machined bearing surface configured to match a particular solder ball array pattern and solder ball size. Individual solder ball recesses are provided in precise locations integrated into the bearing surface for receiving each solder ball of the array. Each recess is in turn served by a vacuum port. The vacuum ports must be precisely located within each of the recesses, and must be significantly smaller than the solder ball size in order to prevent the solder ball from being pulled into the vacuum chamber of the pick-up head, and to prevent the solder ball from being damaged by contact with the rim of the port where it meets the recess. The precision machining required, sometimes including holes in the bearing surface of 60 micrometers in diameter or smaller, makes pick-up heads used in the arts costly and time-consuming to manufacture. Machining problems are sometimes compounded by efforts to use materials particularly suited for semiconductor processing equipment, such as certain types of stainless steel or other alloys requiring slow milling speeds and low feed rates. This is particularly problematic in light of the fact that any given pick-up head may be used only for a particular solder ball array configuration, and for only a very limited range of solder balls sizes.

Due to these and other technological challenges, improved solder ball placement tools and related methods would be useful and advantageous in the arts. The present invention is directed to overcoming, or at least reducing the effects of one or more of the problems with the present state of the art.

### SUMMARY OF THE INVENTION

In carrying out the principles of the present invention, in accordance with preferred embodiments thereof, the invention provides improved solder ball placement tools with enhanced efficiency and adaptability for various solder ball sizes and solder ball array patterns.

According to one aspect of the invention, apparatus for positioning solder balls in a desired array on a surface includes a vacuum head body configured to direct a vacuum force through a permeable vacuum plate enclosing a vacuum chamber. A stencil adjacent to the outer surface of the permeable vacuum plate includes numerous solder ball niches configured to capture solder balls when a vacuum force is applied through the vacuum chamber. The vacuum head is adapted for positioning over a supply of solder balls, capturing a number of solder balls, repositioning over a surface for receiving solder balls, and releasing the solder balls onto the surface.

According to another aspect of the invention, in a preferred embodiment, solder ball positioning apparatus includes a porous metallic permeable vacuum plate.

According to another aspect of the invention, in a particular preferred embodiment, solder ball positioning apparatus includes a sintered metal permeable vacuum plate.

According to another aspect of the invention, a preferred embodiment includes solder ball positioning apparatus having a stencil made from etched metal.

According to yet another aspect of the invention, a preferred embodiment of a solder ball positioning system includes a moveable vacuum head with a body configured to direct a vacuum force through a vacuum chamber. A permeable vacuum plate encloses the vacuum chamber. Also included in the system are interchangeable stencils for individual attachment adjacent to the vacuum plate. Each stencil includes solder ball niches configured to capture solder balls for positioning by the moveable vacuum head.

The invention has advantages including but not limited to providing versatile, adaptable, and efficient solder ball placement tools for use in semiconductor device manufacturing processes, which may provide tool preparation efficiencies, and decreased costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of solder ball placement apparatus according to the invention;

FIG. 2 is a cutaway macro side view of a portion of the preferred embodiment of solder ball placement apparatus according to the invention shown in FIG. 1; and

FIG. 3 is an exploded bottom perspective view of an example of a preferred embodiment of a solder ball placement system according to the invention.

References in the detailed description correspond to like references in the drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

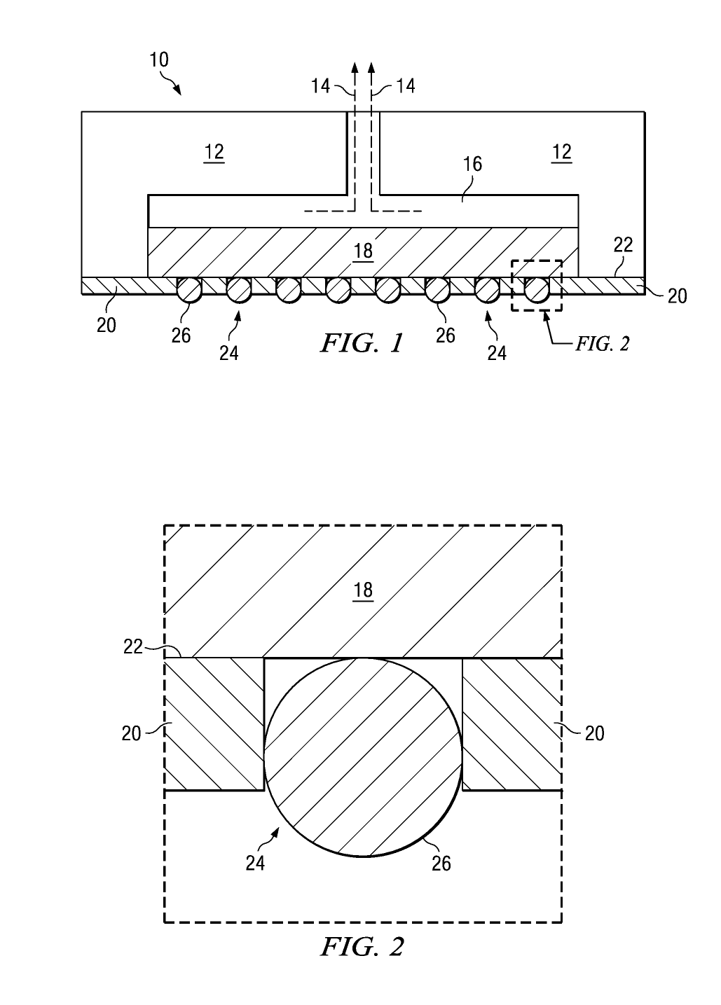

The invention provides solder ball positioning apparatus, systems, and methods for placement of solder balls useful in semiconductor device manufacturing processes. Referring primarily to FIG. 1, apparatus 10 for positioning solder balls on a surface for semiconductor device package assembly is shown. A vacuum head body 12 is configured to direct a vacuum force, indicated by arrow 14, by way of a vacuum chamber 16 connected to an associated vacuum source (not shown). A vacuum plate 18 encloses the vacuum chamber 16. The vacuum plate 18 is made from permeable material, preferably a porous metallic plate, for example, a plate of sintered metal such as stainless steel or monel. Monel is a trademark of Special Metals Corporation for a series of stainless metal alloys, primarily composed of nickel and copper, with trace amounts of iron, manganese, silicon, sulfur and carbon, and sometimes small amounts of aluminum and/or titanium. Monel is a preferred high-strength, corrosion-resistant alloy, although other materials may also be used. Preferably, the permeable vacuum plate 18 may be realized by sintering, a process known in the arts for forming objects from a metal powder by heating the powder at a temperature below its melting point. Through chemical or mechanical processes, a fine powder of metal, such as monel in this example, is produced and compacted into the desired shape and heated, i.e., sintered, during which process the particles of the powder join together to form a strong, cohesive, permeable vacuum plate 18. A stencil 20 is attached adjacent to the outer surface 22 of the vacuum plate 18. The stencil 20 has numerous solder ball niches 24 incorporated into its surface.

The solder ball niches 24 are preferably more-or-less cylindrical apertures perforating the stencil 20 and configured to capture solder balls 26 (not part of the invention). Now referring primarily to FIG. 2, it can be seen in this macro view of a portion of the solder ball placement tool 10 that the niche 24 prevents lateral movement of the solder ball 26 therein. The vacuum force 14 exerted through the permeable vacuum plate 16 from within the chamber 16 prevents the solder ball 26 from falling out of the niche 24, and the surface 22 of the permeable vacuum plate 18 prevents the solder ball 26 from being drawn into the vacuum chamber 16 by the action of the vacuum force 14. Preferably, the stencil 20 has an array of niches 24 arranged in the same manner as a pattern of solder pads on a suitable receiving surface, such as a BGA substrate. The solder ball niches 24 have diameters which are slightly larger than the diameter of the solder balls 26 for the intended implementation, preferably about 10% larger. In use, the vacuum head 10 may be moved to pick up solder balls 26 within the stencil 20 niches 24 by way of the vacuum force 14, may be positioned over a surface prepared for the receiving solder balls 26, and may be caused to release the solder balls 26 from the stencil 20 niches 24 onto the surface by relaxing, e.g., interrupting or diminishing, the vacuum force 14. The stencil 20 is preferably made from a flat sheet of metal by patterning and etching techniques familiar in the semiconductor device manufacturing arts, although other techniques, such as drilling, may also be used.

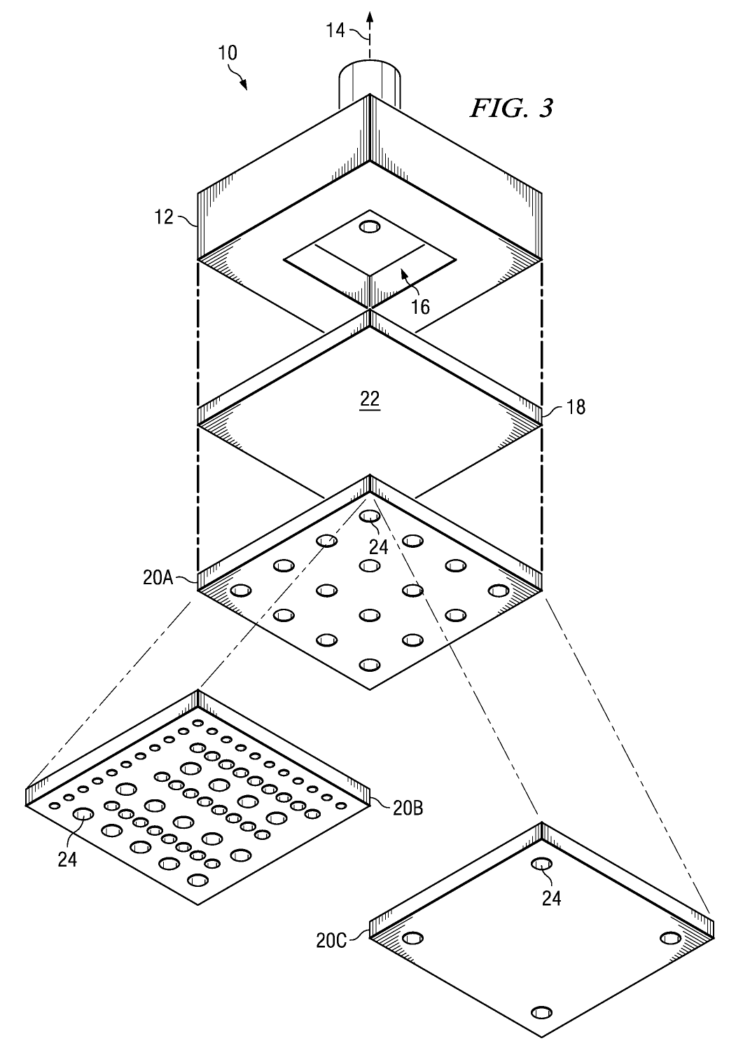

An alternative overview of apparatus and systems 10 for solder ball placement is shown in the exploded bottom perspective view of FIG. 3. It is contemplated that the invention may be used to provide benefits and advantages in semiconductor device manufacturing processes by the use of interchangeable stencils, e.g., 20A, 20B, 20C, with the same vacuum head 12 and permeable vacuum plate 18 assembly. As shown, the stencils 20A, 20B, 20C, may be provided with niches 24 of various sizes arranged in various patterns according to the needs of the practitioners of the invention. The interchangeable stencils 20A, 20B, 20C, may preferably be manufactured using processing techniques known in the arts. Thus, the combination of a permeable vacuum plate 18 used with a readily manufacturable stencil 20 (FIG. 1), or assortment of stencils e.g., 20A, 20B, 20C, provides advantageous cost and efficiency benefits heretofore unattained in the art.

The methods and systems of the invention provide one or more advantages including but not limited to providing solder ball placement tools useful in the semiconductor device manufacturing arts with adaptable, efficient, and cost-effective characteristics. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

I claim:

1. Apparatus for positioning solder balls in a desired array on a surface, comprising:
a vacuum head body configured to direct a vacuum force through a vacuum chamber;
a permeable vacuum plate enclosing the vacuum chamber; and
a stencil adjacent to the permeable vacuum plate, further comprising a plurality of solder ball niches configured to capture solder balls; wherein
the vacuum head may be used to pick up solder balls within the solder ball niches by way of vacuum force, and may be caused to release the solder balls from the solder ball niches by relaxing the vacuum force.

2. Solder ball positioning apparatus according to claim 1 wherein the permeable vacuum plate further comprises a porous metallic plate.

3. Solder ball positioning apparatus according to claim 1 wherein the permeable vacuum plate further comprises a sintered metal plate.

4. Solder ball positioning apparatus according to claim 1 wherein the stencil further comprises etched metal.

5. Solder ball positioning apparatus according to claim 1 wherein the stencil further comprises drilled metal.

6. Solder ball positioning apparatus according to claim 1 wherein the stencil further comprises a plurality of solder ball niches configured in an array corresponding to an array of solder pads on the receiving surface.

7. Solder ball positioning apparatus according to claim 1 wherein the permeable vacuum plate further comprises stainless steel.

8. Solder ball positioning apparatus according to claim 1 wherein the permeable vacuum plate further comprises monel.

9. A solder ball positioning system comprising:
a moveable vacuum head having a body configured to direct a vacuum force through a vacuum chamber;
a permeable vacuum plate enclosing the vacuum chamber; and
a plurality of interchangeable stencils for individually attaching adjacent to the permeable vacuum plate, each stencil further comprising a plurality of solder ball niches configured to capture solder balls; whereby
the moveable vacuum head may be used to pick up solder balls within the solder ball niches by way of vacuum force, may be positioned over a surface for receiving solder balls, and may be caused to release the solder balls from the solder ball niches onto the surface by relaxing the vacuum force.

10. The solder ball positioning system according to claim 9 wherein the permeable vacuum plate further comprises a porous metallic plate.

11. The solder ball positioning system according to claim 9 wherein the permeable vacuum plate further comprises a sintered metal plate.

12. The solder ball positioning system according to claim 9 wherein the stencil further comprises metal etched with an array of solder ball niches.

13. A method of placing an arrangement of solder balls on a surface comprising the steps of:
providing a moveable vacuum head having a permeable vacuum plate;
preparing the vacuum head for receiving a plurality of solder balls by affixing a stencil adjacent to the permeable vacuum plate, the stencil further comprising an arrangement of a plurality of solder ball niches for receiving solder balls;
applying a vacuum force through the permeable vacuum plate in order to capture a plurality of solder balls within the niches;
positioning the vacuum head with captured solder balls over the surface; and
relaxing the vacuum force, thereby releasing the solder balls from the niches onto the surface.

14. The method according to claim 13 further comprising the step of employing one or more interchangeable stencils with the permeable vacuum plate.

15. The method according to claim 13 further comprising the step of etching one or more interchangeable stencil in preparation for use with the permeable vacuum plate.

16. The method according to claim 13 further comprising the step of drilling one or more interchangeable stencil in preparation for use with the permeable vacuum plate.

17. The method according to claim 13 further comprising the step of providing a porous metallic permeable vacuum plate.

18. The method according to claim 13 further comprising the step of providing a porous sintered metal permeable vacuum plate.

19. The method according to claim 13 further comprising the step of providing a porous stainless steel permeable vacuum plate.

20. The method according to claim 13 further comprising the step of providing a porous monel permeable vacuum plate.
